(19) United States
(12) Patent Application Publication
(10) Pub. No.: US 2014/0026012 A1
(43) Pub. Date: Jan. 23, 2014

(54) SEMICONDUCTOR MEMORY DEVICE AND METHOD FOR OPERATING THE SAME

(71) Applicant: Ji-Hyun KIM, Gyeonggi-do (KR)

(72) Inventor: Ji-Hyun KIM, Gyeonggi-do (KR)

(21) Appl. No.: 13/602,413

(22) Filed: Sep. 4, 2012

(30) Foreign Application Priority Data
Jul. 19, 2012 (KR) 10-2012-0078844

(51) Int. Cl. G11C 29/00

(52) U.S. Cl. 714/763; 714/E11.001

(57) ABSTRACT

A semiconductor memory device includes an error correction code (ECG) result generation block configured to receive a decision voltage, to perform an ECC operation, and to output ECC information, and a decision voltage control block configured to control a voltage level adjustment width of the decision voltage in response to the ECC information. As described above, the semiconductor memory device according to an embodiment of the present invention may perform diverse ECC operations by controlling the voltage level adjustment width of the decision voltage VR that is used during the ECC operation, and through the diverse ECC operations, the time for performing an ECC operation may be reduced and the operation efficiency of the ECC operation may be increased.

### CROSS-REFERENCE TO RELATED APPLICATIONS

The present application claims priority of Korean Patent Application No. 10-2012-0078844, filed on Jul. 19, 2012, which is incorporated herein by reference in its entirety.

### BACKGROUND

1. Field

Exemplary embodiments of the present invention relate to a semiconductor designing technology, and more particularly, to a semiconductor memory device that performs an error correction code (ECC) operation.

2. Description of the Related Art

Semiconductor memory devices are generally divided into a volatile memory device, such as a Dynamic Random Access Memory (DRAM) device and a Static Random Access Memory (SRAM) device, and a non-volatile memory device, such as a Programmable Read Only Memory (PROM) device, an Erasable PROM (EPROM), an electrically EPROM (EEPROM), and a flash memory device. The major feature that distinguishes the volatile memory device from the non-volatile memory device is whether the data stored in memory cells are retained or not after a predetermined time.

In other words, the volatile memory device does not retain the data stored in its memory cells after a predetermined time passes, whereas the non-volatile memory device retains the data stored in its memory cells after the predetermined time passes. Therefore, the volatile memory device is required to perform a refresh operation retain the data, and the non-volatile memory device does not have to perform the refresh operation. Because the feature of the non-volatile memory device is appropriate for pursuing low power and high integration, it is widely used as a storage media for a portable device.

Meanwhile, a flash memory device among non-volatile memory devices stores data in memory cells through a program operation and an erase operation. The program operation is an operation for accumulating electrons in a floating gate of a transistor that constitute a memory cell, while the erase operation means an operation for discharging the accumulated electrons out of the floating gate of the transistor. The flash memory device stores a data of ‘0’ or ‘1’ in a memory cell through the operations, senses the amount of electrons accumulated in the floating gate during a read operation, and decides whether the data stored in the memory cell is a ‘0’ data or a ‘1’ data based on the sensing result.

As described above, one memory cell stores a data of ‘0’ or ‘1’. This means that a one-bit data is stored in one memory cell, and the memory cell is referred to as a single-level cell. In these days, a scheme for storing more than one-bit data in one memory cell is being adopted, and this kind of a memory cell is referred to as a multi-level cell. The single-level cell requires a single threshold voltage, which is a decision voltage, to decide whether the data stored in the memory cell is ‘0’ or ‘1’. The multi-level cell requires multiple decision voltages. For example, the multi-level cell requires at least three decision voltages to decide whether the data stored in the memory cell is ‘00’, ‘01’, ‘10’, or ‘11’.

Meanwhile, the data stored in the flash memory device has a predetermined data distribution based on the corresponding data value. The data distribution may overlap with an adjacent data distribution, and due to the overlapping, the data outputted based on a decision voltage may be different from the actually stored data during a read operation. To overcome the concern, the flash memory device is provided with a method for alleviating the concern, and the use of an Error Correction Code (ECC) is one of such methods. An error correction code is an additional code that is inputted along with a data. The flash memory device performs a data detection operation and a data correction operation for a data whose value is erroneously decided through an ECC operation that uses the error correction code.

As technology makes progress, the width of data distribution is becoming narrower and narrower, and this signifies that it becomes easy to distinguish a data. However, the gap between neighboring data distributions is getting narrow due to a low-power consuming operation, and this means that much part of the data distributions overlap with each other. Therefore, it is still important to perform an ECC operation.

FIG. 1 is a flowchart describing an ECC operation of a typical semiconductor memory device.

Referring to FIG. 1, the ECC operation of the typical semiconductor memory device includes reading in step S110, deciding whether a correction is possible by performing an ECC operation in step S120, correcting the data in step S130, and raising a decision voltage by Vt in step S140.

In step S110, a data stored in a memory cell is read based on the initial decision voltage, which is a pre-set voltage. In step S120, an ECC operation is performed on the data that is read in step S110 and it is decided whether the data is correctable or not by performing the ECC operation. If the data is decided to be correctable in the step S120 (which is ‘Yes’), the data is corrected in step S130 and the ECC operation is ended. If the data is decided in the step S120 that it is not correctable (which is ‘No’), the decision voltage is raised by a predetermined voltage level Vt and the process of the step S110 is performed again. Herein, the read operation is performed in the step S110 by using a decision voltage that is increased by the predetermined voltage level Vt from the initial decision voltage.

As described above, the decision voltage is increased by the predetermined voltage level Vt based on the result of the step S120. Although not illustrated in the drawing, when the voltage level of the decision voltage reaches a limit, the semiconductor memory device reaches a limit. Then, semiconductor memory device generates information that the data cannot be corrected through the ECC operation. Therefore, the number of ECC operations to be performed is decided based on the value of the predetermined voltage level Vt, which is an increment of the decision voltage. In other words, when the predetermined voltage level Vt is too big, the number of ECC operations to be performed is too small to perform a desired correction operation. Conversely, when the predetermined voltage level Vt is too small, it takes a long time to perform the ECC operation. In short, the value of the predetermined voltage level Vt affects the performance of the semiconductor memory device.

### SUMMARY

Exemplary embodiments of the present invention are directed to a semiconductor memory device that may control the voltage level adjustment width of a decision voltage that is used for an error correction code (ECC) operation.

In accordance with an exemplary embodiment of the present invention, a semiconductor memory device includes an ECC result generation block configured to receive a decision voltage, to perform an ECC operation, and to output ECC information, and a decision voltage control block configured to control a voltage level adjustment width of the decision voltage in response to the ECC information.

The decision voltage control block may include a control signal generator for generating a control signal for adjusting the voltage level adjustment width of the decision voltage in response to the ECC information, and a decision voltage generator for generating the decision voltage having a voltage level corresponding to the control signal.

In accordance with another exemplary embodiment of the present invention, a method for operating a semiconductor memory device includes deciding the number of failure data by performing an error correction code (ECC) operation based on a decision voltage, controlling the decision voltage by a voltage value corresponding to the number of failure data to produce a controlled decision voltage, and performing the ECC operation again based on the controlled decision voltage.

The controlling of the decision voltage may include controlling the decision voltage by a first voltage, and controlling the decision voltage by a second voltage which is different from the first voltage.

In accordance with yet another exemplary embodiment of the present invention, a method for operating a semiconductor memory device includes deciding the number of failure data by performing an error correction code (ECC) operation based on a decision voltage, applying a profile corresponding to the number of failure data to the decision voltage to produce a controlled decision voltage, and performing the ECC operation again based on the controlled decision voltage.

The applying of the profile to the decision voltage may include sequentially controlling the decision voltage based on the profile, and deciding whether a data is correctable or not, through the ECC operation, based on the controlled decision voltage obtained in the sequential controlling of the decision voltage based on the profile.

The semiconductor memory device in accordance with an exemplary embodiment of the present invention may control the voltage level adjustment width of a decision voltage that is used for an ECC operation based on the number of failure data.

### BRIEF DESCRIPTION OF THE DRAWINGS

FIG. 1 is a flowchart describing an error correction code (ECC) operation of a typical semiconductor memory device.

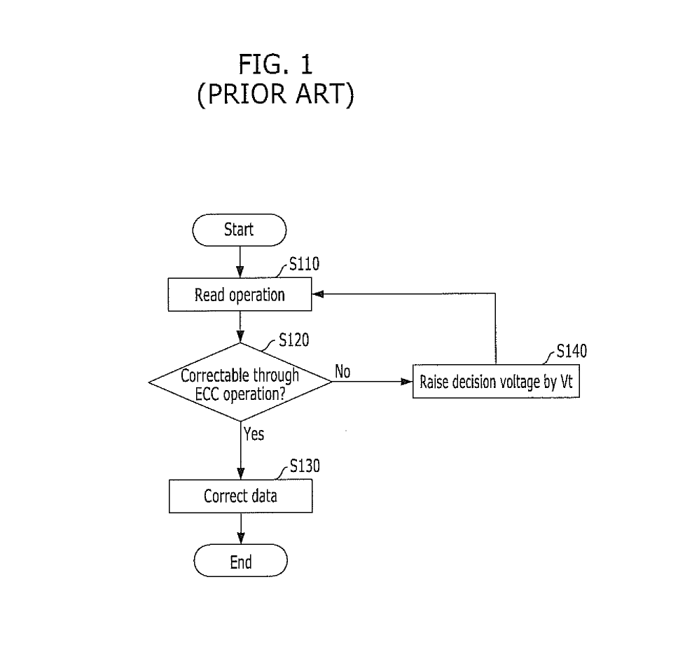

FIG. 2 is a block view illustrating a partial structure of a semiconductor memory device in accordance with an embodiment of the present invention.

FIG. 3 is a circuit diagram illustrating a decision voltage generator 222 of FIG. 2.

FIG. 4 is a flowchart describing an ECC operation of a semiconductor memory device in accordance with an embodiment of the present invention.

FIG. 5 is a flowchart describing an ECC operation of a semiconductor memory device in accordance with another embodiment of the present invention.

FIG. 6 is a flowchart describing a step S560 of FIG. 5.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

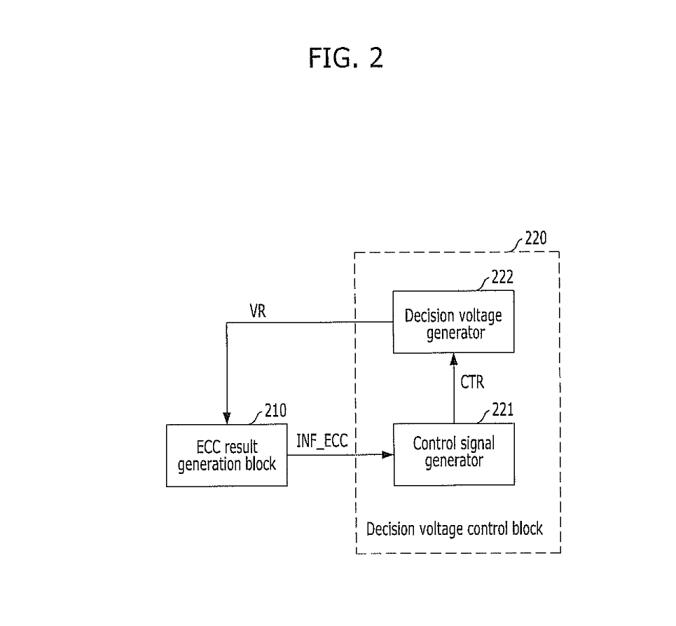

FIG. 2 is a block view illustrating a partial structure of a semiconductor memory device in accordance with an embodiment of the present invention.

Referring to FIG. 2, the semiconductor memory device includes an error correction code (ECC) result generation block 210 and a decision voltage control block 220.

The ECC result generation block 210 generates ECC information INF_ECC that represents the number of failure data after an ECC operation. The ECC result generation block 210 receives a decision voltage VR and performs an ECC operation.

The decision voltage control block 220 controls the voltage level adjustment width of the decision voltage VR in response to the ECC information INF_ECC. The decision voltage control block 220 includes a control signal generator 221 and a decision voltage generator 222. The control signal generator 221 generates a control signal CTR for generating the voltage level adjustment width of the decision voltage VR based on the ECC information INF_ECC, and the decision voltage generator 222 generates a decision voltage VR that has a voltage level corresponding to the control signal CTR.

Hereafter, the relationship between the ECC information INF_ECC and the control signal CTR in accordance with an embodiment of the present invention is briefly described.

The ECC result generation block 210 performs an ECC operation based on the initial decision voltage VR, and then performs an ECC operation based on a decision voltage VR that is controlled based on the control signal CTR. The initial decision voltage VR and the subsequent controlled decision voltage VR are different in their voltage level. The control signal CTR generated in the control signal generator 221 is used to control the voltage level difference, which is a voltage level adjustment width. Herein, the control signal CTR corresponds to the ECC information INF_ECC, and the ECC information INF_ECC is the information that represents the number of failure data occurring during the ECC operation based on the decision voltage VR. After all, the semiconductor memory device in accordance with the exemplary embodiment of the present invention may control the voltage level adjustment width of the decision voltage VR based on the number of failure data, which is the ECC information INF_ECC.

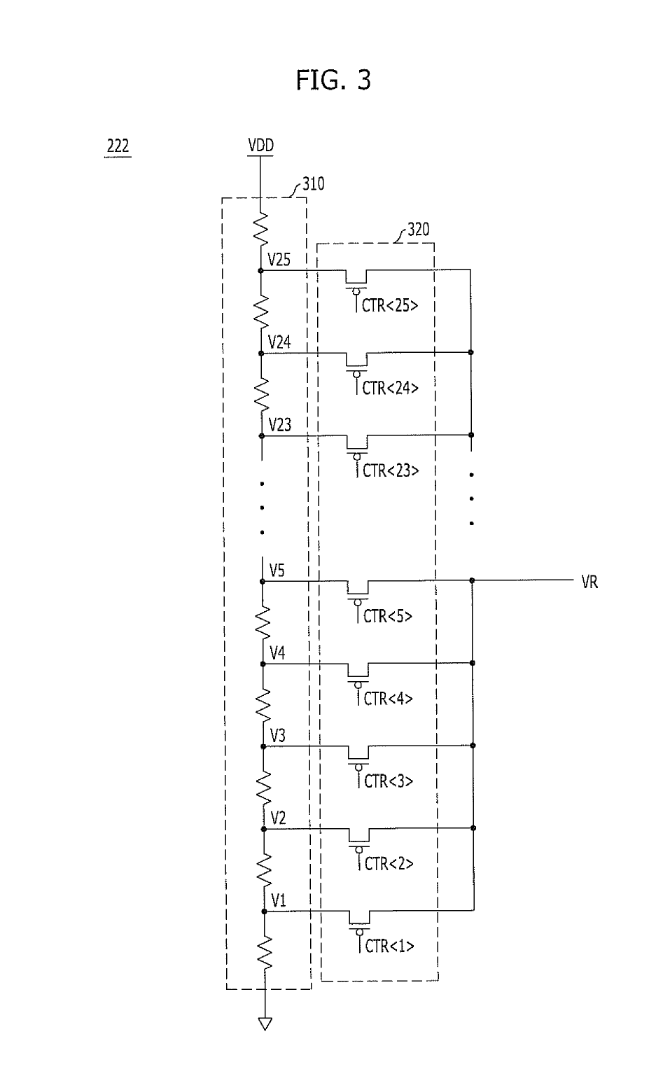

FIG. 3 illustrates a circuit diagram of a decision voltage generator 222 of FIG. 2.

Referring to FIG. 3, the decision voltage generator 222 includes a voltage dividing unit 310 and a selection output unit 320.

The voltage dividing unit 310 divides the voltage level of a power source voltage VDD into a plurality of divided voltages V1, V2, . . . , V25, and the voltage dividing unit 310 includes a plurality of resistors that are serially coupled. The selection output unit 320 outputs a divided voltage corresponding to a control signal CTR<1:25> among the multiple divided voltages V1, V2, . . . , V25 as the decision voltage VR. The selection output unit 320 includes MOS transistors that are coupled corresponding to the divided voltages V1, V2, . . . , V25.

For the sake of convenience in description, it is assumed as an example that the voltage dividing unit 310 generates 25 divided voltages V1, V2, . . . , V25 and the number of the control signal CTR<1:25> that corresponds to the 25 divided voltages V1, V2, . . . , V25 is 25 as well.

Hereafter, the circuit operation of the decision voltage generator 222 is briefly described. For the sake of convenience in description, it is assumed that the initial decision voltage VR is set to a first divided voltage V1.

Referring to FIGS. 2 and 3, the ECC result generation block 210 receives the first divided voltage V1, which is the initial decision voltage VR, and performs an ECC operation and outputs the number of failure data that are detected during the ECC operation as the ECC information INF_ECC. The control signal generator 221 enables one among second to 25^{th} control signals CTR<2:25> based on the ECC information INF_ECC. The control signal to be enabled among the second to 25^{th} control signals CTR<2:25> is decided based on the number of failure data.

First, a case where there are many failure data is described.

The control signal generator 221 enables a first control signal CTR<1> to output the first divided voltage V1 that is initially set up during the ECC operation. Subsequently, the control signal generator 221 enables, for example, a ninth control signal CTR<9> to output the ninth divided voltage V9, which has a relatively longer voltage level adjustment width than the first divided voltage V1, as the decision voltage VR. This decision is based on the ECC information INF_ECC, which represents that there are many failure data. In other words, when there are many failure data, the ninth control signal CTR<9> that is higher by 8 voltage level adjustment widths than the initial decision voltage, which is the first divided voltage V1, is decided as the decision voltage VR.

Hereafter, a case where there are relatively a few failure data is described.

The control signal generator 221 enables, for example, a fourth control signal CTR<4> to output a fourth divided voltage V4 that has a relatively shorter voltage level adjustment width from the first divided voltage V1, as the decision voltage VR. This decision is based on the ECC information INF_ECC, which represents that there are a few failure data. In other words, when there are a small number of failure data, the fourth control signal CTR<4> that is higher by 3 voltage level adjustment widths than the initial decision voltage, which is the first divided voltage V1, may be decided as the decision voltage VR.

The semiconductor memory device in accordance with the exemplary embodiment of the present invention may control the voltage level adjustment width of the decision voltage VR as described above based on the number of failure data that are detected during an ECC operation. Although the exemplary embodiment of the present invention shows a case where the voltage level adjustment width is controlled by three voltage level adjustment widths and eight voltage level adjustment widths, the voltage level adjustment width of the decision voltage VR may be controlled more or less than them based on how semiconductor memory device is designed.

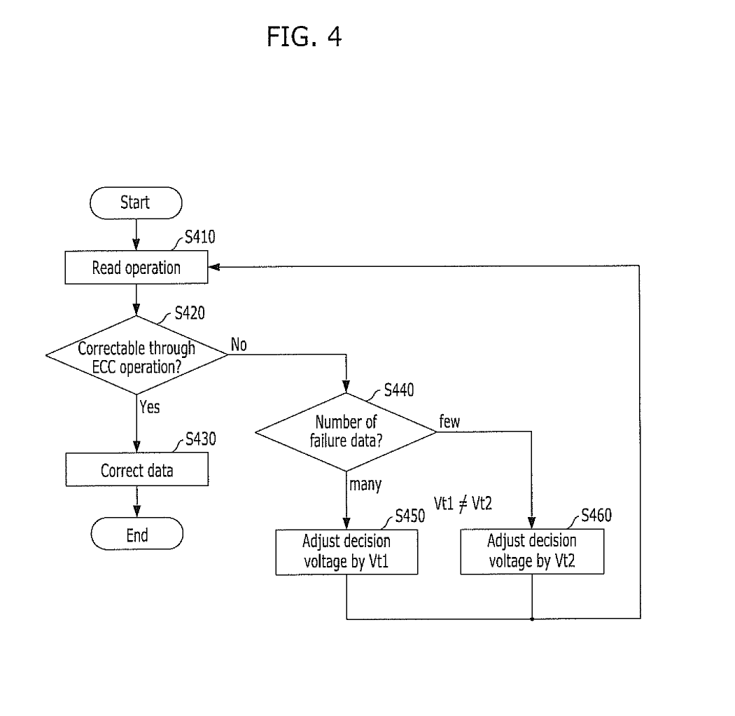

FIG. 4 is a flowchart describing an ECC operation of a semiconductor memory device in accordance with the exemplary embodiment of the present invention.

Referring to FIG. 4, the ECC operation includes performing a read operation in step S410, deciding whether the data is correctable or not when the ECC operation, correcting a data in step S430, deciding the number of failure data in step S440, controlling the decision voltage VR by a first voltage Vt1 in step S450, and controlling the decision voltage VR by a second voltage Vt2 in step S460.

In step S410, a data is read out of a memory cell based on the initial decision voltage VR. In step S420, an ECC operation is performed on the data that is read in the step S410 and whether the data is correctable or not through the ECC operation is decided. If it is decided in step S420 that the data is correctable (“Yes” in the flowchart), the data is corrected in step S430 and the ECC operation is ended. If it is decided in step S420 that the data is not correctable (“No” in the flowchart), the number of failure data is figured out based on the initial decision voltage VR in step S440. If it is turned out in the step S440 that there are many failure data (“many” in the flowchart), the decision voltage VR is controlled by the first voltage Vt1 in step S450 and a read operation is performed again in the step S410. If it is turned out in the step S440 that there are a few failure data (“few” in the flowchart), the decision voltage VR is controlled by the second voltage Vt2 in step S460 and a read operation is performed again in the step S410. Herein, the first voltage Vt1 has a different level from the level of the second voltage Vt2. For example, the level of the first voltage Vt1 may be higher than the level of the second voltage Vt2.

The semiconductor memory device in accordance with the embodiment of the present invention may detect the number of failure data through the ECC operation and control the decision voltage VR by the first voltage Vt1 or the second voltage Vt2 based on the number of failure data. The decision voltage VR being controllable by the first voltage Vt1 or the second voltage Vt2 signifies that the ECC operation may be secured with that much diversity and flexibility.

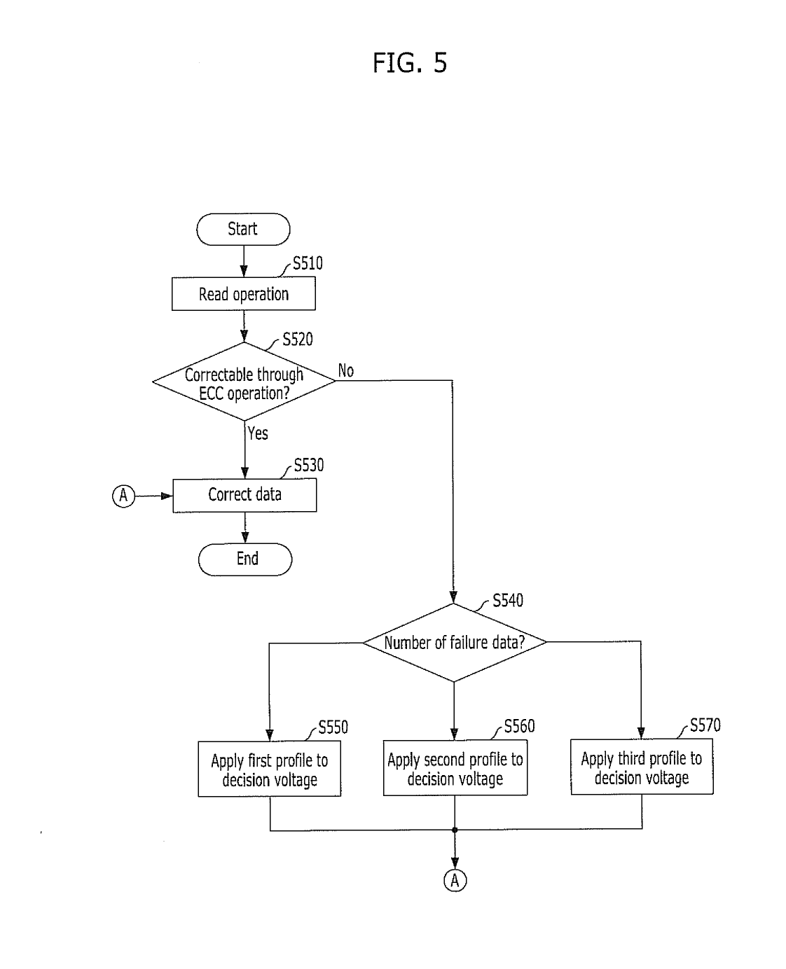

FIG. 5 is a flowchart describing an ECC operation of a semiconductor memory device in accordance with another exemplary embodiment of the present invention. In the embodiment shown in FIG. 5, the decision voltage VR is controlled based on a predetermined profile, and the profile is a variation value of the decision voltage VR. This will be described in detail again in the following Table 1.

Referring to FIG. 5, the ECC operation of a semiconductor memory device in accordance with the embodiment of the present invention includes performing a read operation in step S510, deciding whether a data is correctable or not through an ECC operation in step S520, correcting the data in step S530, deciding the number of failure data in step S540, applying a first profile to a decision voltage VR in step S550, applying a second profile to a decision voltage VR in step S560, and applying a third profile to a decision voltage VR in step S570. Compared with the embodiment shown in FIG. 4, the embodiment of FIG. 5 includes the steps S550 to S570 where the first to third profiles are applied to the decision voltage VR, and the description on the other operations is omitted herein for the sake of convenience in description.

Although the exemplary embodiment of FIG. 5 shows the example where the first to third profiles are applied to the decision voltage VR, a structure where more than one profile may be applied to the decision voltage based on how the semiconductor memory device is designed is also within the scope and concept of the present invention.

In step S550, the first profile is applied to the decision voltage VR, and the second profile which is different from the first profile is applied to the decision voltage VR in step S560. In step S570, the third profile which is different from the first profile and the second profile is applied to the decision voltage VR.

The following Table 1 is an example of the first to third profiles. The voltage values shown in Table 1 are exemplary voltage values accumulated in the decision voltage VR.

| | Vt1 | Vt2 | Vt3 | Vt4 | Vt5 | Vt6 |
|---|---|---|---|---|---|---|
| 1^{st} profile | +300 mV | +300 mV | +40 mV | +20 mV | | |
| 2^{nd} profile | +150 mV | +150 mV | +40 mV | +40 mV | +20 mV | |
| 3^{rd} profile | +10 mV | −20 mV | +30 mV | −40 mV | +50 mV | −60 mV |

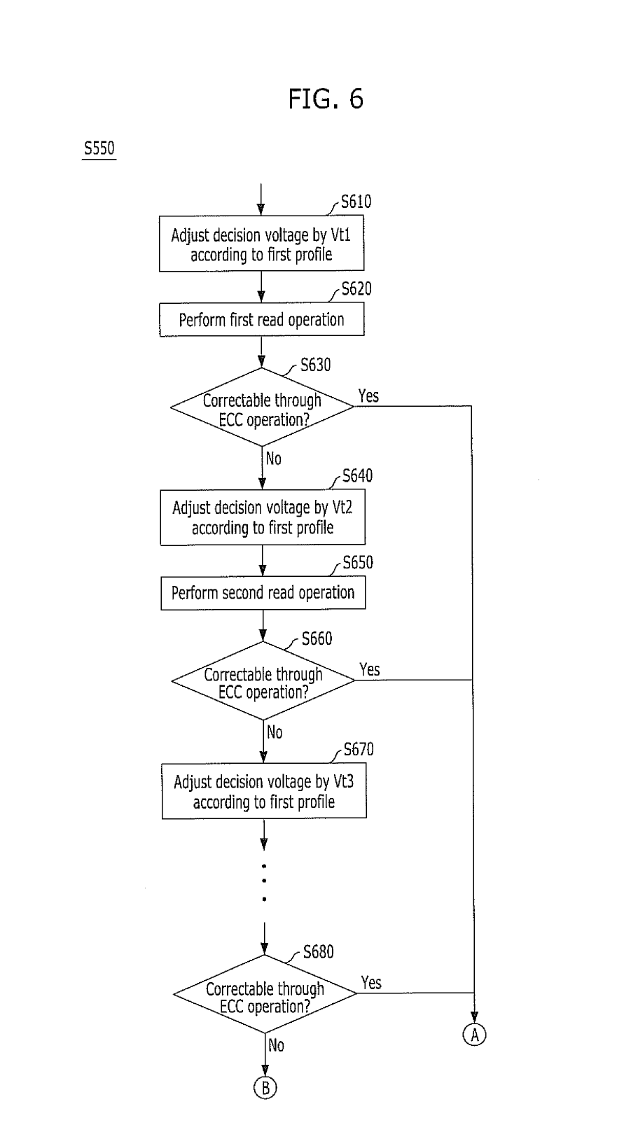

As shown in Table 1, each of the first to third profiles is set to more than one different voltage values, and the number of the voltage values may be different based on how semiconductor memory device is designed. In this exemplary embodiment of the present invention, the voltage level of the decision voltage VR is sequentially changed based on the first to third profiles. The relationship between the decision voltage VR and the profile is described below in detail with reference to FIG. 6.

FIG. 6 is a flowchart describing a step S550 of FIG. 5. A case where the first profile is applied to the decision voltage VR among the first to third profiles is representatively described hereafter.

Referring to FIG. 6, the step S550 includes controlling the decision voltage VR by a first voltage Vt1 based on the first profile in step S610, performing a first read operation in step S620, deciding whether a data is correctable through an ECC operation in step S630, controlling the decision voltage VR by a second voltage Vt2 based on the first profile in step S640, performing a second read operation in step S650, deciding whether a data is correctable through an ECC operation in step S660, controlling the decision voltage VR by a third voltage Vt3 based on the first profile in step S670, and deciding whether a data is correctable through an ECC operation in step S680.

Referring to Table 1 and FIG. 6, the first voltage Vt1 based on the first profile is applied to the decision voltage VR in step S610. In other words, the first voltage Vt1 becomes +300 mV based on the first profile, and the +300 mV is reflected in the decision voltage VR. In step S620, the first read operation is performed based on the decision voltage VR to which the first voltage Vt1 is applied, and it is decided in step S630 whether a data is correctable through the ECC operation. If the data is correctable through the ECC operation in the step S630 (“yes” in the drawing), the data is corrected in the step ‘A’, which is the step S530 of FIG. 5 and the ECC operation is ended. If the data is not correctable through the ECC operation in the step S630 (“no” in the drawing), the second voltage Vt2 according to the first profile, which is +300 mV, is reflected to the decision voltage VR that is changed in the step S610. Through the operation, the voltages of the first profile are sequentially reflected to the decision voltage VR.

In the drawing, step ‘B’ is a moment when the first profile is ended. Although not illustrated in the drawing, another profile other than the first profile may be applied, and it is also possible to generate information representing that a data is not correctable through an ECC operation based on how the semiconductor memory device is designed.

The semiconductor memory device in accordance with the exemplary embodiment of the present invention may perform an ECC operation by applying a profile that corresponds to the number of failure data to the decision voltage VR. Also, in the exemplary embodiment of FIG. 5, each of the steps S550, S560, and S570 to which the first to third profiles are applied to the decision voltage VR includes the steps S630, S660, and S680 where it is decided whether a data is correctable or not through an ECC operation as shown in FIG. 6. Because the step S540 of deciding the number of failure data during the ECC operation is performed only once in the embodiment of FIG. 5, which is different from the embodiment of FIG. 4, the time taken for the FCC operation may be reduced accordingly.

As described above, the semiconductor memory device according to an embodiment of the present invention may perform diverse ECC operations by controlling the voltage level adjustment width of the decision voltage VR that is used during the ECC operation, and through the diverse ECC operations, the time for performing an ECC operation may be reduced and the operation efficiency of the ECC operation may be increased.

According to an embodiment of the present invention, the performances of a semiconductor memory device may be improved through an ECC operation by controlling the voltage level adjustment width of a decision voltage that is used for an ECC operation and thus performing diverse ECC operations.

While the present invention has been described with respect to the specific embodiments, it will be apparent to those skilled in the art that various changes and modifications may be made without departing from the spirit and scope of the invention as defined in the following claims.

The embodiments of the present invention exemplarily illustrate the case where a decision voltage VR is generated by sequentially accumulating the voltage values of Table 1 onto the initial decision voltage VR. However, it is also possible to generate the decision voltage VR by reflecting different voltage values to the initial decision voltage VR based on how a semiconductor memory device is designed.

The positions and kinds of logic gates and transistors illustrated in the embodiment described above may be realized differently according to the polarity of an input signal.

What is claimed is:

1. A semiconductor memory device, comprising:
an error correction code (ECC) result generation block configured to receive a decision voltage, to perform an ECC operation, and to output ECC information; and
a decision voltage control block configured to control a voltage level adjustment width of the decision voltage in response to the ECC information.

2. The semiconductor memory device of claim 1, wherein the decision voltage control block includes:
a control signal generator for generating a control signal for adjusting the voltage level adjustment width of the decision voltage in response to the ECC information; and
a decision voltage generator for generating the decision voltage having a voltage level corresponding to the control signal.

3. The semiconductor memory device of claim 1, wherein the ECC information represents the number of failure data that are detected during the ECC operation based on the decision voltage.

4. The semiconductor memory device of claim 2, wherein the decision voltage generator includes:
a voltage dividing unit for dividing a power source voltage into a plurality of divided voltages; and
a selection output unit for outputting a divided voltage corresponding to the control signal among the multiple divided voltages, as the decision voltage.

5. A method for operating a semiconductor memory device, comprising:
deciding the number of failure data by performing an error correction code (ECC) operation based on a decision voltage;
controlling the decision voltage by a voltage value corresponding to the number of failure data to produce a controlled decision voltage; and
performing the ECC operation again based on the controlled decision voltage.

6. The method of claim 5, wherein the controlling of the decision voltage includes:
controlling the decision voltage by a first voltage; and
controlling the decision voltage by a second voltage which is different from the first voltage.

7. The method of claim 5, wherein in the controlling of the decision voltage,
if there are many failure data, the decision voltage is controlled by a first voltage, and if there are a small number of failure voltages, the decision voltage is controlled by a second voltage which is lower than the first voltage.

8. The method of claim 5, further comprising:
deciding whether a data is correctable or not through the ECC operation; and
correcting the data based on a decision result for whether the data is correctable or not, through the ECC operation.

9. A method for operating a semiconductor memory device, comprising:
deciding the number of failure data by performing an error correction code (ECC) operation based on a decision voltage;
applying a profile corresponding to the number of failure data to the decision voltage to produce a controlled decision voltage; and
performing the ECC operation again based on the controlled decision voltage.

10. The method of claim 9, wherein the applying of the profile to the decision voltage includes:
sequentially controlling the decision voltage based on the profile; and
deciding whether a data is correctable or not, through the ECC operation, based on the controlled decision voltage obtained in the sequential controlling of the decision voltage based on the profile.

11. The method of claim 10, further comprising:
correcting a data based on a decision result for whether the data is correctable or not, through the ECC operation, based on the controlled decision voltage.

12. The method of claim 9, wherein the profile includes a plurality of profiles that correspond to the failure data, and each of the profiles has more than one different voltage values.
